(19) United States
(12) Patent Application Publication
(10) Pub. No.: US 2008/0227226 A1
(43) Pub. Date: Sep. 18, 2008

(54) Semiconductor substrate, manufacturing method of a semiconductor device and testing method of a semiconductor device

(75) Inventors: Shigeru Fujii, Kawasaki (JP); Yoshikazu Arisaka, Kawasaki (JP); Hitoshi Izuru, Kawasaki (JP); Kazuhiro Tashiro, Kawasaki (JP); Shigeyuki Maruyama, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/153,481

(22) Filed: May 20, 2008

Related U.S. Application Data
(62) Division of application No. 11/062,488, filed on Feb. 23, 2005.

(30) Foreign Application Priority Data
Nov. 11, 2004 (JP) 2004-328061

(51) Int. Cl. H01L 21/66; H01L 21/304

(52) U.S. Cl. 438/10; 438/462; 257/E21.238; 257/E21.531

(57) ABSTRACT

A semiconductor substrate eliminates a restriction caused by a width of scribe lines so as to increase a number of semiconductor elements formed on the semiconductor substrate. A plurality of semiconductor element areas are formed by forming a plurality of unit exposed and printed areas, each of which contains the semiconductor element areas. A first scribe line extends between the semiconductor element areas formed within the unit exposed and printed area. A second scribe line extends between the unit exposed and printed areas. A width of the first scribe line is different from a width of the second scribe line.

### CROSS-REFERENCE TO RELATED APPLICATIONS

This application is a division of U.S. application Ser. No. 11/062,488, filed on Feb. 23, 2005 which is based upon and claims the benefit of priority from the prior Japanese Patent Application No. 2004-328061, filed on Nov. 11, 2004, the entire contents of which are incorporated herein by reference.

### BACKGROUND OF THE INVENTION

1. Field of the Invention

The present invention relates to a semiconductor substrate, a manufacturing method of a semiconductor device and a testing method of a semiconductor device and, more particularly to a technique to forming a plurality of semiconductor elements (semiconductor chips) on a semiconductor substrate (wafer) in a lump and a testing method of the thus-formed semiconductor device.

2. Description of the Related Art

In order to raise a manufacture efficiency of semiconductor devices, it is a common practice to form a plurality of semiconductor elements (semiconductor chips) on one semiconductor substrate (wafer) in one lump. After, a plurality of semiconductor elements formed on the semiconductor substrate in one lump are subjected to an electric tests, etc., as they are on the semiconductor substrate, and, thereafter, the semiconductor elements are separated into individual elements (individual chip) and are subjected to a packaging process if necessary. Formation of semiconductor elements on the semiconductor substrate includes a preliminary process including a so-called photo-lithography process.

In the photo-lithography process, a reticle (a negative plate for printing) having a pattern for forming a predetermined semiconductor element area or for forming electrodes and wiring is prepared beforehand, and an exposure process is applied to a photosensitive resin layer (photoresist layer) which is formed on a film formed on a main surface of the semiconductor substrate. After performing a developing process on the photosensitive resin layer, the film and the like are selectively removed by etching using the remaining photosensitive resin layer, which results in a pattern of the film formed on the semiconductor substrate.

In recent years, the size of a semiconductor substrate has been increased (8-inch diameter to 100-inch diameter), and it is difficult to cover an entire main surface of a semiconductor substrate by one sheet of reticle. Accordingly, one semiconductor substrate is divided into a plurality of areas so as to perform an exposure process using the reticle on an individual area basis. That is, exposure and printing is performed sequentially on the areas one by one while relatively moving the semiconductor substrate and the reticle to each other. It should be noted that a plurality of patterns, each of which corresponds to one semiconductor element, are formed in one reticle.

The semiconductor elements formed on the semiconductor substrate are individualized by the semiconductor substrate being cut by a dicing blade. Therefore, areas which are cut and removed by the dicing blade, that is, dicing areas are provided between the patterns corresponding to the semiconductor elements that are formed by exposure and printing using the reticle.

Usually, a width of the dicing area is set substantially equal to a width of the dicing blade so that the entire dicing area between adjacent semiconductor elements is cut off and removed by one time of the dicing process. An example of the printing pattern formed on the semiconductor substrate according to the conventional processing method is shown in FIG. 1.

As mentioned above, the exposure and printing according to the reticle is performed on a plurality of areas sequentially one by one. Here, 1 time of the exposure printing area by the reticle is called a reticle area. The dicing area shaved off by a dicing blade is referred to a scribe line or a dicing line. In the example shown in FIG. 1, 4 reticle areas 2-1 to 2-4 are indicated by dotted lines, and each reticle area contains a pattern 4 corresponding to 16 semiconductor elements of 4 rows×4 columns. Within each reticle area 2-1-2-4, the interval of the pattern 4 corresponding to the semiconductor device of one row on the semiconductor substrate is equal to a width W1 of the scribe line (dicing area), and is defined by the pattern on the reticle.

On the other hand, in order to also make a width W2 of the area between the reticle area 2-1 and the adjacent reticle area 2-2 substantially equal to the width W1 of the scribe line W1, a width of the dicing area of an outer peripheral portion of each reticle area is set equal to about ½ (half) of the scribe line in the reticle area. That is, the positions of the reticle areas 2-1 to 2-4 on the semiconductor substrate are adjusted so that the width W2 as a result of connection of the dicing areas on the outer peripheries of adjacent reticle areas is substantially equal to the width of the dicing blade so as to be equal to the width W1 of the scribe line.

The setting of the width of the scribe line is applied not only to the transverse direction W of the pattern 4 corresponding to the semiconductor elements but also to a width L in a longitudinal direction so that all widths of the scribe lines are equal to each other. Conventionally, the intervals (widths W1 and W2, widths L1 and L2) between the patterns 4 corresponding to the semiconductor elements formed on the semiconductor substrate are set equal to a width of a dicing blade so as to attempt to improve an efficiency of dicing.

Moreover, when testing many semiconductor elements formed on a semiconductor substrate before individualizing, an electric connection is made simultaneously to the plurality of semiconductor elements (for example, two elements in the example of FIG. 1) so as to test the plurality of semiconductor elements simultaneously to attempt an improvement in the test.

In the example of FIG. 1, a test is applied simultaneously to tow semiconductor elements 4-1a and 4-1b among the semiconductor elements arranged along a line (the two elements have the same function and, thus, the same patterns are formed), and, then, adjacent two semiconductor elements 4-1c and 4-1d are tested simultaneously. Further, adjacent two semiconductor elements 4-2a and 4-2b are tested simultaneously, and, thereafter, two semiconductor elements are sequentially tested simultaneously in the same manner. Thus, even if a test is performed, for example, on the semiconductor elements 4-1a and 4-2a in the method in which tow semiconductor elements are simultaneously tested (a case where a number of semiconductor elements formed in one reticle area is an odd number), it is easy to separate the semiconductor elements from each other by using a dicing blade since the interval W2 between the semiconductor elements concerned is set equal to the interval W1 of other semiconductor elements. That is, the above-mentioned test method is based on an arrangement of the semiconductor elements in which each interval of the semiconductor elements on the semiconductor substrate is equal to a width of a scribe line. On the other hand, it is necessary to provide alignment marks for positioning or the like around the semiconductor elements on the semiconductor substrate.

It should be noted that such marks are usually provided on scribe lines and are removed when dicing along the scribe lines since the marks are necessary for a manufacturing process but not necessary for completed semiconductor elements. That is, the scribe lines also serve as areas for providing alignment marks and the like. For this reason, the width of the scribe line must be larger than an alignment mark. However, if all scribe lines have a width sufficient to provide alignment marks thereon, the width of the scribe lines are increased, which causes an increase in an area occupied by the scribe lines with respect to the area of the semiconductor substrate and a decrease in the number of semiconductor substrates that can be formed on one sheet of a semiconductor substrate.

Thus, there is suggested in Japanese Laid-Open Patent Application No. 2000-124185 to arrange alternately a narrow scribe line and to arrange alignment marks only on the wide scribe lines so as to increase the number of semiconductor elements that can be formed on one sheet of the semiconductor substrate. Moreover, Japanese Laid-Open Patent No. 63-250119 suggests that a width of scribe lines extending in a longitudinal direction is different from a width of scribe lines extending in a transverse direction as one in which scribe lines having different widths are formed on one semiconductor substrate.

As mentioned above, according to the arrangement of semiconductor devices in which a width of scribe lines between the semiconductor elements is uniform and the dicing area of the outer periphery of the reticle area is equal to ½ of the scribe line, a scribe area having the same width is formed in all areas between the semiconductor elements formed on the semiconductor substrate. Thus, all scribe lines can be cut by a dicing blade of the same width with the width of the scribe lines, which achieves efficient dicing process.

However, a number of semiconductor elements arranged in one reticle area is not always optimum. In order to set the width of the scribe lines constant, there is a restriction arose in the arrangement of the semiconductor elements in the reticle area, which results in that the number of the semiconductor elements which can be provided in one reticle area cannot be increased further.

In recent years, thickness of semiconductor substrates is tend to be reduced so as to achieve a further miniaturization and integration of semiconductor devices, and, thus, such a semiconductor substrate having a reduced thickness can be cut using a dicing blade having a small thickness (or width). However, as mentioned above, the arrangement of semiconductor elements in which widths of scribe lines are equal to each other in the semiconductor substrate, and, as a result, there are many cases in which a dicing blade having a width larger than a minimum width necessary for cutting the semiconductor substrate having a reduced thickness.

If the dicing blade having the necessary minimum thickness (width) is used, the width and area of the dicing area in a semiconductor substrate can be reduced further and it can become possible to increase the area for forming semiconductor elements, which results in an increase in the number of semiconductor elements formed on one semiconductor substrate. However, as mentioned-above, there is a case in which a dicing blade having a necessary minimum thickness (width) cannot be effectively applied in the arrangement of semiconductor elements in which widths of the scribe lines are equal to each other so as to achieve further efficient dicing, and, thus, there is a problem in which the number of semiconductor elements formed on one semiconductor substrate cannot be increased further.

### SUMMARY OF THE INVENTION

It is a general object of the present invention to provide an improved and useful semiconductor substrate, an improved and useful manufacturing method and testing method of a semiconductor device in which the above-mentioned problems are eliminated.

A more specific object of the present invention is to provide a semiconductor substrate and a manufacturing method and testing method of a semiconductor device which eliminates a restriction caused by a width of scribe lines so as to increase a number of semiconductor elements formed on the semiconductor substrate.

In order to achieve the above-mentioned objects, there is provided according to one aspect of the present invention a semiconductor substrate on which a plurality of semiconductor element areas are formed by forming a plurality of unit exposed and printed areas, each of which contains the semiconductor element areas, the semiconductor substrate comprising: a first scribe line extending between the semiconductor element areas formed within the unit exposed and printed area; and a second scribe line extending between the unit exposed and printed areas, wherein a width of the first scribe line is different from a width of the second scribe line.

In the semiconductor substrate according to the present invention, it is preferable that the width of the first scribe line is a minimum width by which the semiconductor substrate can be cut. Additionally, it is preferable that the width of the first scribe line is smaller than the width of the second scribe line. Further it is preferable that the width of the first scribe line is determined based on a thickness of the semiconductor substrate.

In the semiconductor substrate according to the present invention, a plurality of scribe lines may include the first scribe line extend within the each of the unit exposed and printed areas, and widths of the scribe lines may be different from each other. An alignment mark may be arranged on the second scribe line.

Additionally, there is provided according another aspect of the present invention a manufacturing method of a semiconductor device, comprising: a first exposing and printing step of forming a first exposed and printed area on a semiconductor substrate using a reticle having a pattern corresponding to a plurality of semiconductor elements that are separated by a first scribe line; a second exposing and printing step of forming a second exposed and printed area on the semiconductor substrate so that a second scribe line extends between the first exposed and printed area and the second exposed and printed area, which has a width larger than a width of the first scribe line; and a step of individualizing the semiconductor elements by cutting and separating the semiconductor substrate along the first scribe line and the second scribe line. The above-mentioned manufacturing method may further comprise setting the width of the first scribe line to a minimum width by which the semiconductor substrate can be cut.

Additionally, there is provided according to another aspect of the present invention a testing method of a semiconductor device in which a plurality of semiconductor element areas are formed on a semiconductor substrate by forming a plurality of unit exposed and printed areas including a first unit exposed and printed area and a second unit exposed and printed area each of which contains the semiconductor element areas, the testing method comprising: simultaneously testing the semiconductor elements located at corresponding positions in the first unit exposed and printed area and the second unit exposed and printed area. The above-mentioned testing method may further comprise correcting a position at which an electric contact is made to the semiconductor element area within the second exposed and printed area in accordance with a positional error between the first exposed and printed area and the second exposed and printed area.

As mentioned above, according to the present invention, the semiconductor substrate can be cut along the first scribe line between adjacent semiconductor element areas formed in one reticle area (the unit exposed and printed area) using a dicing blade having a necessary minimum thickness (width). Therefore, an area of the semiconductor substrate necessary for dicing (removed by cutting) is reduced, thereby increasing an area for forming semiconductor elements in one sheet of semiconductor substrate is increased. That is, a number of semiconductor elements formed in one reticle area is increased, which results in an increase in the number of semiconductor elements formed in one sheet of semiconductor substrate.

Moreover, according to the testing method of a semiconductor device according to the present invention, since a plurality of semiconductor elements located at corresponding positions in different exposed and printed areas can be tested simultaneously, the plurality of semiconductor elements can be electrically contacted and tested simultaneously even if widths of the scribe lines are different from each other.

Other objects, features and advantages of the present invention will become more apparent from the following detailed description when read in conjunction with the accompanying drawings.

### BRIEF DESCRIPTION OF THE DRAWINGS

FIG. 1 is a plan view of a printing pattern formed on a semiconductor substrate according to a conventional processing method;

FIG. 2 is a plan view of a semiconductor substrate on which a plurality of semiconductor elements are formed by a manufacture method of a semiconductor device according to the present invention;

FIG. 3 is an enlarged view of a part A surrounded by dotted lines of FIG. 2;

FIG. 4 is an illustration for explaining a testing method of simultaneously testing two semiconductor elements over two reticle areas;

FIG. 5 is an illustration for explaining a testing method of testing four semiconductor elements over four reticle areas;

FIG. 6 is a plan view showing an example where scribe lines having different widths to each other exist in one reticle area;

FIG. 7 is a cross-sectional view showing an example of a prober, which can test simultaneously two semiconductor elements formed in different reticle areas; and

FIG. 8 is a plan view of an XYθ-moving mechanism of a probe card shown in FIG. 7.

### DETAILED DESCRIPTION OF THE PREFERRED EMBODIMENTS

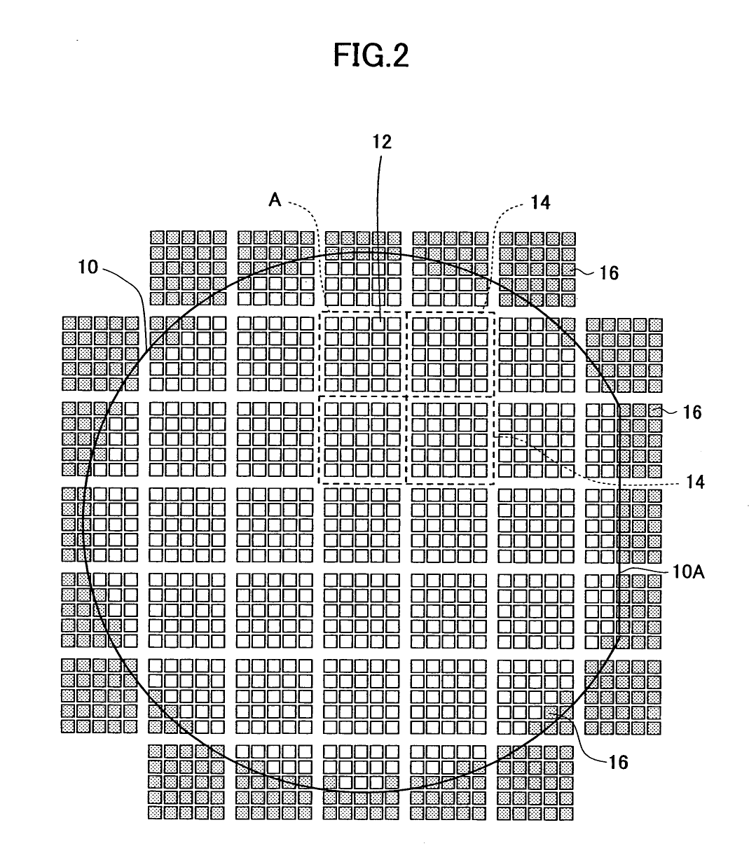

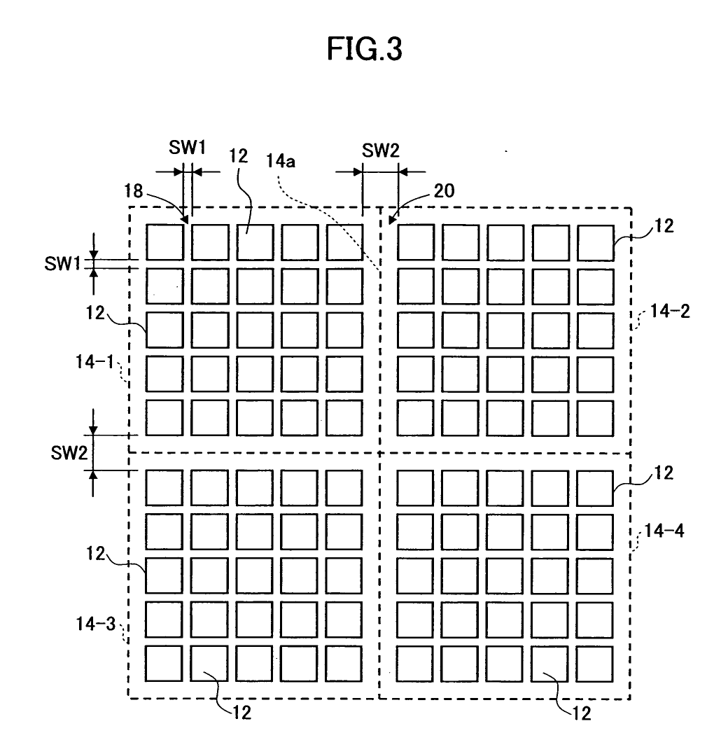

A description will now be given, with reference to the drawings, of embodiments of the present invention. First, a description will be given, with reference to FIG. 2 and FIG. 3, of a semiconductor substrate according to an embodiment of the present invention.

FIG. 2 is a plan view of a semiconductor substrate on which a plurality of semiconductor elements are formed by a manufacture method of a semiconductor device according to the present invention. FIG. 3 is an enlarged view of a part A surrounded by dotted lines of FIG. 2.

FIG. 2 indicates a state where a plurality of semiconductor elements 12 are formed on a semiconductor substrate 10 made of silicon (Si). In FIG. 2, areas 14 defined by dashed lines are areas exposed and patterned simultaneously using one sheet of reticle (each area is a unit exposed and printed area, which is hereinafter referred to as a reticle area). Twenty-five semiconductor elements 12 of 5 rows×5 columns are provided in each of the reticle area 14. Of course, a number of the semiconductor elements 12 formed in each reticle area 14 is not limited to 25 pieces, and is properly selected based on the size of the semiconductor elements, the size of the reticle or the width of the scribe lines.

In the present invention, a number of the semiconductor elements 12 formed in one reticle area 14 is set to be maximum by selecting suitably, as mentioned later, without making all widths of scribe lines equal to each other. The reticle areas 14 are located in a lattice-like arrangement so as to cover an entire main surface of the semiconductor substrate 14 of a circular shape (normally has an orientation flat 10A). It should be noted that although it is unnecessary or inappropriate to form the semiconductor element 12 in an edge area and areas out of the semiconductor substrate 10 in FIG. 2, such a semiconductor element 12 is indicated as an invalid semiconductor area 16 so as to show a form of arrangement of the reticle areas 14.

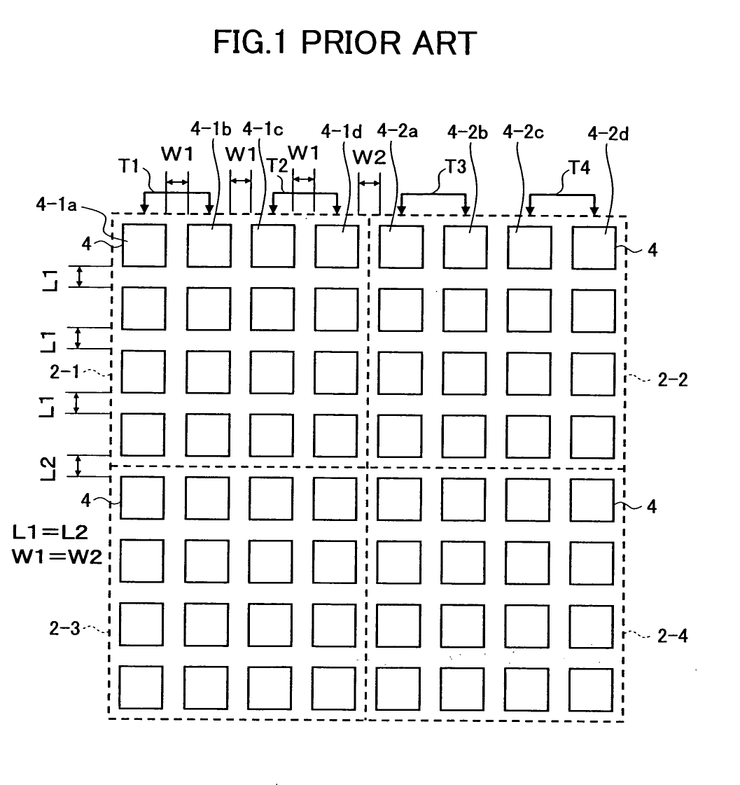

An area of the part A containing a plurality of reticle areas 14 in FIG. 2 is shown in FIG. 3. In FIG. 3, a width SW1 of each scribe line 18 (first scribe line) corresponding to an area between adjacent semiconductor elements 12 in each reticle area 14 is smaller than a width SW2 of each scribe line 20 (second scribe line) which extends along a boundary line between adjacent reticle areas 14. As mentioned above, conventionally, the positions of the semiconductor elements 12 in the reticle area 14 are determined so that the width SW1 of the scribe lines 18 and the width SW2 of the scribe lines 20 are equal to each other as shown in FIG. 1. However, in the present invention, the restriction to equalize widths of all scribe lines is eliminated, and the widths of the scribe lines are determined according to a viewpoint that a number of semiconductor elements formed in one reticle is maximized. In the present embodiment, in order to maximize the number of semiconductor elements formed in one reticle area, the width SW1 of the scribe lines between adjacent semiconductor elements 12 in each reticle area 14 is set equal to a minimum width of a dicing blade, which can cut the semiconductor substrate 10.

As mentioned above, recently, a thickness of semiconductor substrates tends to decrease, and a width of a dicing blade by which a semiconductor substrate can be cut has decreased in recent years. For example, if a width of a dicing blade which can cut a semiconductor substrate of a conventional thickness is 120 micrometers, a width of a dicing blade which can cut a semiconductor substrate with a reduced thickness has decreased to even 40 μm-60 μm. Therefore, if a dicing blade of a necessary minimum thickness (width) is used, the area of the semiconductor shaved off by cutting is decreased, thereby correspondingly increasing an area in which semiconductor elements are formed. Thus, a number of semiconductor elements that can form in one reticle area is increased, which results in an increase in the number of semiconductor elements formed in one semiconductor substrate. That is, in the present embodiment, a scribe line width corresponding to the thickness (width) of the dicing blade, which is a minimum size by which a semiconductor substrate can be cut, is set to an area between the plurality of semiconductor elements formed in one reticle area.

Then, the exposure and printing is sequentially applied to the semiconductor substrate using the reticle. In the reticle area, a plurality of semiconductor elements (corresponding printed patterns) are gathered into the center portion thereof, and remaining areas on an outer periphery thereof are scribe line areas of the reticle area concerned. That is, in the present embodiment, a plurality of semiconductor elements are separated and arranged in each reticle area with a necessary minimum interval, which is a minimum scribe line width which can cut the semiconductor substrate, and the remaining area in the peripheral portion of the exposed and printed area is set as scribe lines. At this time, the width of the remaining area in the peripheral portion of each reticle area is a value larger than ½ of the scribe line by which the semiconductor substrate can be cut.

By setting the width of the remaining area in the outer periphery of the reticle area to be larger than ½ of the minimum scribe line width by which the semiconductor substrate can be cut, a width of a scribe line (the scribe line 20 in FIG. 3) between the adjacent reticle area becomes larger than the minimum width of the scribe line (the scribe line 18 in FIG. 3) by which the semiconductor substrate can be cut. Therefore, alignment marks or the like can be provided on the scribe line between the adjacent reticle areas. Thus, by determining the width of the scribe lines according to the above-mentioned method, in the present invention, there are provided scribe lines having different widths in one semiconductor substrate. Since the scribe line between adjacent reticle areas has a width larger than the width of the scribe line in one reticle area, the scribe line between adjacent reticle areas may be cut at once using a dicing blade having a larger thickness, or may be cut by performing a cutting process two times using the dicing blade for cutting the scribe line between adjacent semiconductor elements in one reticle area.

As mentioned above, in the semiconductor substrate according to the present embodiment, a plurality of semiconductor elements are formed in each of a plurality of reticle areas, and a width of a second scribe line extending between adjacent exposed and printed areas is different from a width of a first scribe line extending between adjacent semiconductor elements in each exposed and printed area. The width of the first scribe line is determined based on the thickness of the semiconductor substrate, and preferably be a minimum width by which the semiconductor substrate can be cut.

Moreover, according to the manufacturing method of the semiconductor device according to the present embodiment, a pattern corresponding to a plurality of semiconductor devices is exposed and printed on a semiconductor substrate so as to form first exposed and printed areas by using one sheet of reticle having the pattern corresponding to the plurality of semiconductor elements separated by first scribe lines, which have a width equal to a minimum width by which the semiconductor substrate can be cut, and, then, the reticle is moved, and a second exposed and printed area is formed adjacent to the first exposed and printed area so that the width of a second scribe line extending on a boundary is larger than the width of the first scribe line. Then, exposure and printing is repeated while moving the reticle so as to form the semiconductor elements over a substantially entire surface of the semiconductor substrate. Thereafter, the semiconductor elements are individualized by dicing (separating by cutting) the semiconductor substrate along the first scribe lines and the second scribe lines. That is, the semiconductor substrate is cut using the dicing blade having a minimum width by which the semiconductor substrate can be cut along the first scribe lines so as to individualize the semiconductor elements.

In the present embodiment, although a thin dicing blade is used for cutting the semiconductor substrate, cutting by a laser light may be used instead of the dicing blade cutting since the semiconductor substrate is thinned. In such a case using a laser light, the width of dicing can be reduced to 20 μm-30 μm. Thus, the number of semiconductor elements formed in one reticle area is increased, which results in a further increase in the number of semiconductor elements formed on one sheet of semiconductor substrate.

A description will now be given of a testing method when performing an electrical test on the semiconductor substrate on which semiconductor elements are formed in the above-mentioned embodiments as a state of the semiconductor substrate.

Conventionally, a plurality of semiconductor elements formed on one sheet of the semiconductor substrate are arranged at equal intervals, and for example, as shown in FIG. 1, an electrical contact is made simultaneously to adjacent two semiconductor elements so as to apply an electrical test simultaneously to the two semiconductor element as one unit while sequentially shifting the electrical contact in a transverse direction. The semiconductor elements 4 have the same function and the same electrode arrangement, and are tested simultaneously. Namely, the semiconductor elements 4 indicted by T1 in FIG. 1 are tested simultaneously and after the test is completed, the electrical contact is shifted to the semiconductor elements indicated by T2 so as to perform a test. Similarly, semiconductor elements to make an electrical contact are sequentially shifted so as to perform an electrical test on the semiconductor elements indicated by T3 and T4.

Even if the semiconductor elements are present over two (or more) reticle areas when scribe line widths equal to each other in one sheet of semiconductor substrate, the relative positional relationship between the two adjacent semiconductor elements is constant, and, thus, there is no need to change positions at which the electric contact is made. However, in the present invention, if the width of the scribe lines provided around one reticle area differs from the width of the scribe lines between the semiconductor elements as is in the above-mentioned embodiment, the relative positional relationship (distance) between the semiconductor elements differs from a distance between the semiconductor elements in the reticle area.

Thus, although a plurality of semiconductor elements in one reticle area can be tested simultaneously, a test cannot be applied simultaneously to a plurality of semiconductor elements located over adjacent reticle areas, that is, a first semiconductor element positioned at an end of a first reticle area and a second semiconductor element located at an end of a second reticle area adjacent to the first reticle area and facing the first semiconductor element.

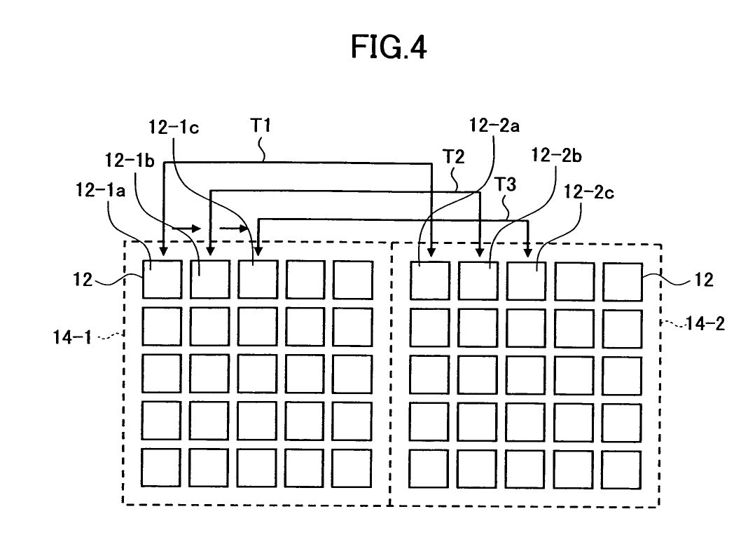

Thus, in the present invention, as shown in FIG. 4, a test is applied by making an electric contact to the semiconductor elements 12, which are located at corresponding positions in a plurality of reticle areas provided on a semiconductor substrate. That is, in FIG. 4, as indicated by T1, the semiconductor element 12-1a in the first reticle area 14-1 and the semiconductor element 12-2a in the second reticle area 14-2 are tested simultaneously. After the test is completed, the electric contact is shifted to the corresponding two semiconductor elements 12-1b and 12-2b indicated by T2, and these semiconductor elements are tested. Subsequently, the electric contact is shifted to corresponding two semiconductor elements 12-1c and 12-2c indicated by T3, and these semiconductor elements are tested. The same test is applied sequentially to other semiconductor elements 12.

Since one sheet of the reticle is moved sequentially so as to form the reticle areas 14, the relative positional relationship between the semiconductor elements within the reticle area 14 is the same between the reticle areas 14. Therefore, if a contactor, which makes the electric contact to the two semiconductor elements indicated by T1, is moved in a transverse direction in the testing method shown in FIG. 4, the contactor is moved to a position above the two semiconductor elements 12 indicated by T2 and, thus, an electric contact can be made to the two semiconductor elements 12 simultaneously. The same is applied to the two semiconductor elements 12 indicated by T3.

Although the testing method for two semiconductor elements 12 in the two reticle areas 14 is show in FIG. 4, the number of semiconductor elements tested simultaneously is not limited to two pieces, and more than two semiconductor elements formed in more than two reticle areas 14 can be tested simultaneously if such a contactor can be constituted. That is, a number of semiconductor elements tested simultaneously can be an arbitrary number equal to or greater than two.

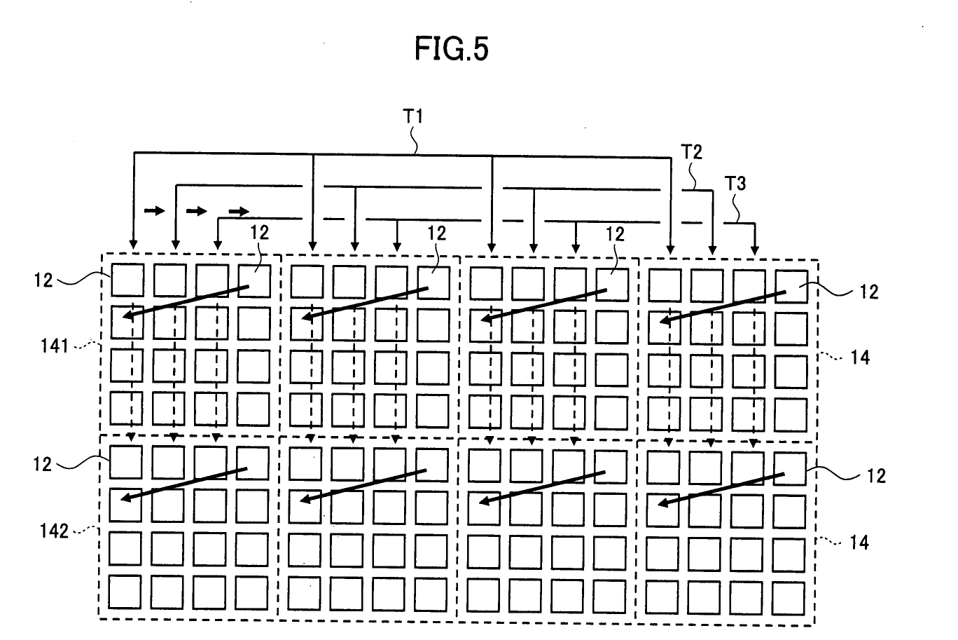

FIG. 5 is an illustration for explaining the testing method in more detail. In the testing method shown in FIG. 5, a test is applied simultaneously to the corresponding four semiconductor elements 12 in an area 141 containing four reticle areas 14 arranged in a transverse direction, the four semiconductor elements 12 located in the four reticle areas 14, respectively. Although the total of 25 semiconductor elements 12 are formed in each reticle area 14 in the arrangement of 5 rows×5 columns in the example shown in FIG. 4, a total of 16 semiconductor elements 12 are formed in each reticle area 14 in an arrangement of 4 rows×4 columns in the example shown in FIG. 5.

In the arrangement shown in FIG. 5, an electric contact is simultaneously taken to the corresponding four semiconductor elements 12 indicated by T1, and a test is simultaneously performed on the four semiconductor elements 12 concerned. Then, an electric contact is simultaneously made to the corresponding four semiconductor elements 12 indicated by T2, and a test is simultaneously performed on the four semiconductor elements 12 concerned. Thereafter, an electric contact is simultaneously made to the corresponding four semiconductor devices 12 indicated by T3, and a test is simultaneously performed on the four semiconductor elements 12.

A test is applied sequentially to corresponding four semiconductor elements 12 simultaneously, and after the test is completed for the semiconductor elements 12 of one row, an electric contact is shifted to a next row and performs a test simultaneously to corresponding four semiconductor elements in the same manner as applied to the semiconductor elements 12 in the upper row. Then, after completing the test on all the semiconductor elements 12 in the area 141, a test is applied to the semiconductor elements in the four reticle areas of a next area 142 in the same manner as is applied to the semiconductor elements 12 in the area 141.

As mentioned above, in the testing method according to the present invention, even if scribe lines having different widths exist in one semiconductor substrate, a test can be simultaneously applied to a plurality of semiconductor elements located at the same position in each of exposed and printed areas over the plurality of exposed and printed areas.

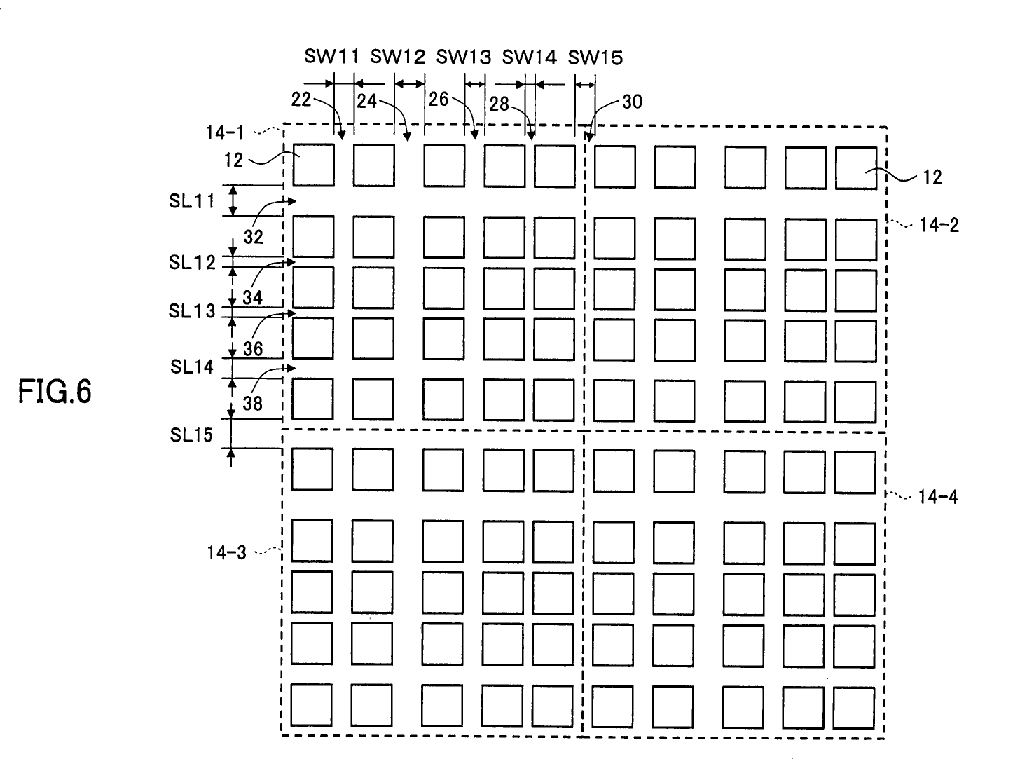

The above-mentioned testing method is applicable to a case where scribe lines of different widths exist in one reticle area as shown in FIG. 6. FIG. 6 is a plan view showing an example where scribe lines having different widths to each other exist in one reticle area.

In FIG. 6, scribe lines 22, 24, 26 and 28 extending in a vertical direction in the first reticle area 14-1 and a scribe line 30 extending along a boundary between the first reticle area 14-1 and the second reticle area 14-2 adjacent to the first reticle area 14-1 have different widths SW11, SW12, SW13, SW14 and SW15, respectively. Similarly, scribe lines 32, 34, 36 and 38 extending in a horizontal direction in the first reticle area 14-1 and a scribe line 40 extending along a boundary between the first reticle area 14-1 and the third reticle area 14-3 adjacent to the first reticle area 14-1 have different widths SL11, SL12, SL13, SL14 and SL15, respectively.

For example, in a so-called test element group (TEG), there is a case where patterns corresponding to different semiconductor elements (different in size, different in function) are formed in one reticle. Additionally, there is a case in which the same kind of semiconductor elements are gathered into a part and a width of a scribe line is increased between groups of different kinds of semiconductor elements. In addition, it is possible to provide scribe lines of different widths in one reticle area in other cases. According to the above-mentioned testing method, since the semiconductor elements arranged at the same position in each reticle area are the same kind of semiconductor element among the semiconductor elements arranged in a reticle unit, a plurality of semiconductor elements can be tested simultaneously over a plurality of reticle areas. In the above-mentioned testing method, an electric contact is made simultaneously to the semiconductor elements located at corresponding positions in a first reticle area and a second reticle area (other reticle areas) so as to perform a test simultaneously on the semiconductor elements.

A so-called prober is used in order to make an electric contact. When simultaneously making a contact with corresponding semiconductor elements in a plurality of reticle areas, probes (contact needles) of a prober are arranged in accordance with a plurality of semiconductor elements to be tested simultaneously in consideration of a size of the reticle area so that the probes can be moved all together to positions corresponding to semiconductor elements to be tested subsequently.

The above-mentioned testing method is on the assumption that the reticle can be moved with high accuracy so that a plurality of exposed and printed areas according the reticle. However, assuming that an accuracy of movement of the reticle is deteriorated for some reasons and the accuracy in positioning of the exposed and printed areas is deteriorated, it is needed to correct the positions of the probes. That is, although the positional relationship between the semiconductor elements formed in each reticle area is not changed, the positional relationship between the semiconductor elements in different reticle areas that are tested simultaneously may be changed. Thus, a change in the relative positions of the reticle areas containing the semiconductor elements tested simultaneously is equal to a change in the relative positions of corresponding semiconductor elements. Then, it is preferable to monitor or detect the positional accuracy between the reticle areas so as to correct positions of the probes when the positional accuracy between the reticle areas is deteriorated.

The correction of the positions of the probes can be achieved by correcting, with respect to probes corresponding to a semiconductor element formed in a first reticle area as a reference, positions of the semiconductor elements formed in a second reticle area in accordance with an offset of position of the reticle concerned.

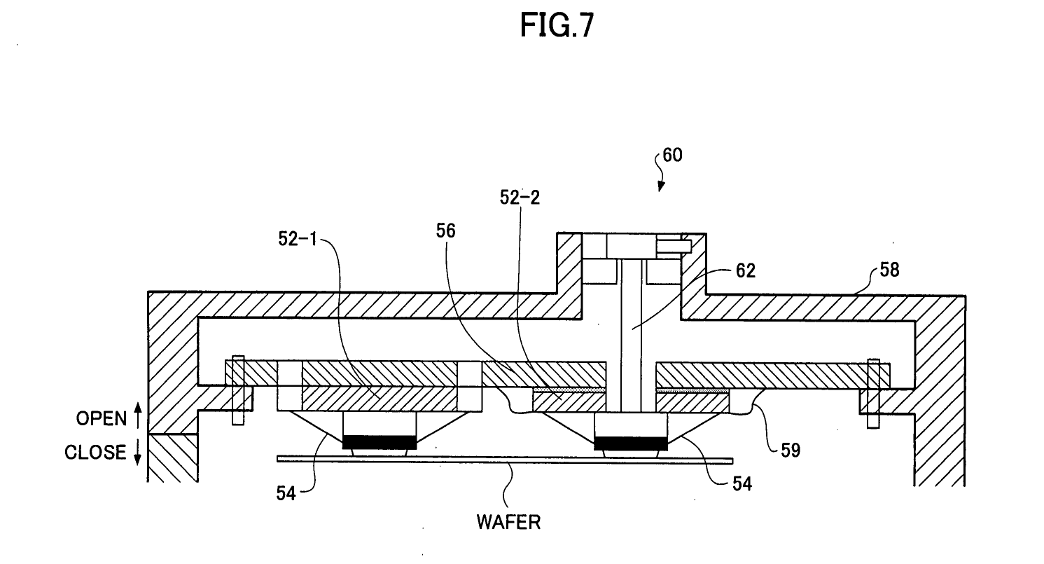

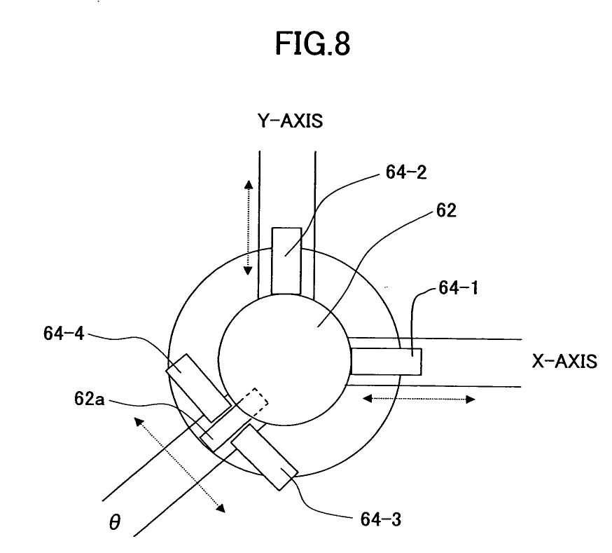

FIG. 7 is a cross-sectional view showing an example of the prober which can test simultaneously two semiconductor elements formed in different reticle areas. FIG. 8 is a plan view of an XYθ-moving mechanism of the probe card shown in FIG. 7.

The prober shown in FIG. 8 has two probe cards 52-1 and 52-2, and each of the probe cards 52-1 and 52-2 has probes (contact needles) 54 for contacting the electrodes of one of the semiconductor elements. Ends of the probes 54 are arranged so as to contact with corresponding electrodes of semiconductor elements formed on a semiconductor substrate. The probe card 52-1 is fixed to a substrate 56, and, on the other hand, the probe card 52-2 is supported by the substrate in a minutely movable manner. That is, the probe card 52-2 is fixed to a movable axis 62 of the XYθ-moving mechanism 60 mounted to a prober housing 58 so as to be minutely movable with respect to the substrate 56 by driving the XYθ-moving mechanism 60. Since the other probe card 52-1 is fixed to the substrate 56, the probe card 52-2 is minutely movable with respect to the probe card 52-1 as a result. In order to make the probe card 52-2 movable, the probe card 52-2 is electrically connected to the substrate 56 by flexible wiring 59.

The XYθ-moving mechanism 60 is capable of minutely moving the movable axis 62 in the X-direction and the Y-direction that are parallel to a main surface of the semiconductor substrate, and also minutely rotatable in the θ-direction within the X-Y plane. In order to drive the movable axis 62 as shown in FIG. 8, the XYθ-moving mechanism 60 has micro-actuators 64-1, 64-2, 64-3 and 64-4 such as piezoelectric elements or magneto-striction elements.

The micro-actuator 64-1 causes the probe card 52-2 to minutely move in the X-direction by minutely moving the drive axis 62 in the X-direction. The micro-actuator 64-2 causes the probe card 52-2 to minutely move in the Y-direction by minutely moving the drive axis 62 in the Y-direction. The micro-actuators 64-3 and 64-4 causes the probe card 52-2 to rotate in the θ-direction by rotating the drive axis 62 in the θ-direction by pressing a protruding pin 62a protruding in a radial direction from the drive axis 62.

According to the prober shown in FIG. 7 and FIG. 8, the position of the probe card 52-2 in contact with the semiconductor element formed in another (the second) reticle area can be corrected with respect to the probe card 52-1 in contact with the semiconductor element formed in a first reticle area, and both the probe cards 52-1 and 52-2 can be positioned with sufficient accuracy to the plurality of semiconductor elements to be tested.

It should be noted that although not shown in FIG. 7, the semiconductor substrate is located on a stage movable in XY-directions so that a test is applied sequentially to the semiconductor elements on the semiconductor substrate by moving the semiconductor elements to be tested to positions directly under the probe cards 51-1 and 51-2 by sequentially moving the semiconductor substrate in the XY-directions.

As mentioned above, according to the present embodiment, an electric contact is made simultaneously to a plurality of semiconductor elements at corresponding positions in each of a plurality of exposed and printed areas so as to simultaneously test the semiconductor elements to which the electric contact has been made. Moreover, when an electric contact is made simultaneously to the plurality of semiconductor elements, the position to make the contact is corrected with respect to at least one of the semiconductor elements in accordance with a positional error between the exposed and printed areas.

As mentioned above, in the semiconductor substrate formed by the manufacturing method of a semiconductor substrate according to the present invention, an interval between adjacent semiconductor elements in one reticle area (exposed and printed area) is selectively set to a minimum width (width of a first scribe line) by which the semiconductor substrate can be cut, and a width of a second scribe line formed between adjacent reticle areas is set larger than the width of the first scribe line. Therefore, a number of semiconductor elements formed on the semiconductor substrate can be increased as compared with the conventional method.

Additionally, according to the testing method of the semiconductor device according to the present invention, semiconductor elements located at corresponding positions are tested simultaneously in a plurality of reticle areas arranged with a wider scribe line therebetween. That is, even if the scribe lines have different widths on the semiconductor substrate, a contact is made simultaneously to a plurality of semiconductor elements located at corresponding positions in a plurality of reticle areas and a test is performed simultaneously to the plurality of semiconductor elements.

The present invention is not limited to the specifically disclosed embodiments, and variations and modifications may be made without departing from the scope of the present invention.

The present application is based on Japanese priority application No. 2004-328061 filed Nov. 11, 2004, the entire contents of which are hereby incorporated herein by reference.

What is claimed is:

1. A manufacturing method of a semiconductor device, comprising:
a first exposing and printing step of forming a first exposed and printed area on a semiconductor substrate using a reticle having a pattern corresponding to a plurality of semiconductor elements that are separated by a first scribe line;
a second exposing and printing step of forming a second exposed and printed area on said semiconductor substrate so that a second scribe line extends between said first exposed and printed area and said second exposed and printed area, which has a width larger than a width of said first scribe line; and
a step of individualizing the semiconductor elements by cutting and separating said semiconductor substrate along said first scribe line and said second scribe line.

2. The manufacturing method as claimed in claim 1, further comprising setting the width of said first scribe line to a minimum width by which said semiconductor substrate can be cut.

3. A testing method of a semiconductor device in which a plurality of semiconductor element areas are formed on a semiconductor substrate by forming a plurality of unit exposed and printed areas including a first unit exposed and printed area and a second unit exposed and printed area each of which contains the semiconductor element areas, the testing method comprising:
simultaneously testing the semiconductor elements located at corresponding positions in the first unit exposed and printed area and the second unit exposed and printed area.

4. The testing method as claimed in claim 3, further comprising correcting a position at which an electric contact is made to the semiconductor element area within said second exposed and printed area in accordance with a positional error between said first exposed and printed area and said second exposed and printed area.
